(19) United States
(12) Patent Application Publication
(10) Pub. No.: US 2002/0062856 A1
(43) Pub. Date: May 30, 2002

(54) Solar collector unit

(75) Inventor: Sean G. Wescott, Eugene, OR (US)

Correspondence Address: DYKAS, SHAVER & NIPPER, LLP, P O BOX 877, BOISE, ID, 83701-0877, US

(73) Assignee: Stellar Technologies, LLC, Boise, ID

(21) Appl. No.: 09/975,897

(22) Filed: Oct. 10, 2001

Related U.S. Application Data
(60) Provisional application No. 60/239,391, filed on Oct. 10, 2000.

(51) Int. Cl. H01L 31/00

(52) U.S. Cl. 136/246; 136/259

(57) ABSTRACT

A rod shaped or tubular solar collector, in which the solar collecting surfaces of the solar collector are pointed at the interior of the rod or tube. A number of tubular configurations are possible, with one configuration being a solid rod of plastic or acrylic surrounded by solar collectors facing the interior of the tube. A light collecting and focusing lens is provided on the end of the tube exposed to sunlight. A light reflecting structure is provided on the opposite end of the tube, which reflects light back into the tube for absorption by solar panels

### REFERENCE TO RELATED APPLICATION

This application is a utility application claiming the priority of provisional application serial No. 60/239,391, filed Oct. 10, 2000, entitled SOLAR ROD DEVICE.

### BACKGROUND OF THE INVENTION

1. Field of the Invention

The present invention generally relates to solar collectors, and more particularly to cylindrical solar collectors with the solar collectors facing towards the center of the cylinder.

2. Background Information

The most common arrangement of solar photovoltaic devices are in flat, rectangular arrays which may consist of flat circular disks or square or rectangular solar collecting modules. These flat, rectangular panels are typically oriented for maximum exposure to sunlight, and thus for maximum electricity production. The underlying principal behind these flat array solar collectors is that in order to get more volts of electricity, you need more surface area of solar collectors exposed to the sun, and a more perpendicular orientation to the sun.

There is another class of solar collectors which are tubular in nature. Almost all of these are a tube in which solar collectors are attached to the outside of the tube with the energy collecting side of the solar collector facing away from the tube. The solar collecting tubes are then placed in reflectors which serve to concentrate the solar energy onto the sides of the tube. These concentrators may be parabolic in cross section, in order to have good efficiency at reflecting sunlight onto the outside of the solar collecting tubes.

There is one solar collector which utilizes a tube and solar collecting panels affixed to the outside of the tube, with the solar collecting surface facing the inside of the tube. This is the patent for Tubular Luminescence Photovoltaic Array, by Robert K. Morris, U.S. Pat. No. 4,687,880. Morris utilizes a large reflector dish 30 in order to concentrate sunlight into the tube of his invention. Morris also utilizes triangularly shaped grooves located on the inside walls of the light tubes in order to cause light which enters the tube to be bounced into the solar collectors on the outside of the tube. Morris is unlike the present invention in several regards. For one thing, the enlarged reflector of Morris prevents a number of the light collecting tubes of Morris from being mounted edge to edge. For another, the inner walls of the light tube of Morris have triangular shaped ridges, which teach away from the idea of passing light to solar collectors through an inner wall with a smooth surface, or through a solid rod of light transparent material. Additionally, the reflector of Morris is dependent upon a double reflector arrangement for collecting light for the light tube. Sunlight enters the reflector dish of Morris, and is bounced into a center reflector which directs sunlight through a light orifice and into the interior of the light tube. With this kind of reflector arrangement, the solar collector of Morris must be oriented directly towards the light source, or the angle of the light will make light reflection and concentration ineffective.

Therefore, it is an object of the invention to provide a solar collector which utilizes a rod or tube with solar collectors facing towards the interior of the tube. It is a further object of the invention that an array of these tubes could be laid closely together, or side by side with only their ends exposed to sunlight, but still have high electricity output. It is a further object of this invention that the amount of electricity per unit of surface area exposed to light is made greater by a highly efficient, tubular solar collector. It is a further object of the invention to provide a solar collector which may be embedded in another object, with only a small surface area exposed for collection of light.

### SUMMARY OF THE INVENTION

These and other objects are accomplished by a solar collecting unit of the invention. The solar collecting unit includes a light rod or light tube, which has a long axis and two ends. The device could be configured with either a solid rod, or with a tube with a hollow center, and although light rod may be used in the text, it is to be understood that the light rod could be solid or hollow. The light rod, if in the form of a tube, also has a light rod wall with a smooth interior surface, and an exterior surface. If in the form of a solid rod, it does not have an interior surface. Its two ends include a light collecting end and a light blocking end, for orientation so that light from a light source enters the light collecting end, travels down the inside of the light rod, and is blocked from leaving the light rod at the light blocking end. The light rod can be made of a sheet of solar collectors, with each solar collector having a collecting side and a non-collecting side. The solar collectors are oriented so that the collecting side faces the interior of the light rod, or in other words, the long axis of the light rod. Each of the solar collectors form an array which has an electrical connection, so that the array of solar collectors are operationally connected so that electricity can flow out of the solar collectors.

The solar collector unit operates by orienting the light rod so that the light collecting end is oriented towards a light source, and the light blocking end is away from the light source. Light from the light source enters the light rod through the light collecting end, passes through the smooth interior surface of the light rod, and strikes one or more of the solar collectors, which produce electricity which flows through the electrical connections. Light which is reflected off the smooth interior surface of the light rod, or which is reflected off the surface of the solar collectors, is reflected back into the light rod, and may be absorbed by a solar collector on the opposite side of the light rod when it strikes that side of the light rod.

The solar collector unit can be designed so that the light tube is formed entirely of solar collectors. The light tube can also be a separate unit such as a cylindrical piece of acrylic. Either configuration of light tubes can have a number of cross sectional shapes and still function well. For instance, the light tube can have a cross sectional shape of a cylinder, a square rod or tube, a triangular rod or tube, a multi-sided rod or tube such as a hexagonal or pentagonal, or can be in any other tubular or rod shape. The light tube can also be conical, so that the points of the cones can be oriented adjacent to each other, and the wide ends of each cone oriented outwardly. In this configuration, a sphere of light rods could be formed, with the points of the cones in the center of the ball, and the surface of the ball covered in the wide end of the cones. If the light tube is a separate unit apart from the solar collectors, the solar collectors need merely to be oriented facing towards the center of the light tube. Flat solar collectors can be used on a cylindrical tube by curving the flat solar collectors around the tube. If the tube is a shape other than cylindrical, the surfaces of the tube can be covered with appropriately shaped solar collectors.

The light blocking end of the light tube can include a concave reflector which extends into the light tube, for reflecting light back toward the light collecting end of the tube. In this way, any light which enters the light tube is likely to eventually be absorbed by a solar collector on the wall. The reflector on the light blocking end can be convex, protruding out in relation to the rod of the light tube and with a reflective coating. It can also be faceted, with a reflective coating and either a convex or concave shape. The light tube can also have the light collecting end sealed, such as with a flat piece of clear plastic, or by a light focusing lens mounted over the light collecting end of the light tube. Such a light focusing end would aid in focusing and directing light into the interior of the light tube.

In one version of the solar collecting unit, the light tube is a solid rod of material which is transparent to light, such as acrylic, glass, plastic, or other similar transparent material. Such a solid light collecting tube can also be configured in many cross sectional shapes such as cylindrical, square tube, triangular tube, multi-sided tube such as pentagonal, hexagonal, etc., or any other configuration of tube, including conical shapes. In one embodiment of the invention, the light focusing lens is approximately equal in diameter to the light tube. This configuration would help in efficiency by allowing an array of light tubes to be very densely packed.

Still other objects and advantages of the present invention will become readily apparent to those skilled in this art from the following detailed description wherein I have shown and described only the preferred embodiment of the invention, simply by way of illustration of the best mode contemplated by carrying out my invention. As will be realized, the invention is capable of modification in various obvious respects all without departing from the invention. Accordingly, the drawings and description of the preferred embodiment are to be regarded as illustrative in nature, and not as restrictive.

### BRIEF DESCRIPTION OF THE DRAWINGS

FIG. 1 is a perspective view of the solar collecting unit.

FIG. 2 is a cross sectional view of the solar collecting unit.

FIG. 3 is a side view of a hexagonal solar collecting unit.

FIG. 4 is a cross sectional view of a hexagonal solar collecting unit.

### DESCRIPTION OF THE PREFERRED EMBODIMENTS

While the invention is susceptible of various modifications and alternative constructions, certain illustrated embodiments thereof have been shown in the drawings and will be described below in detail. It should be understood, however, that there is no intention to limit the invention to the specific form disclosed, but, on the contrary, the invention is to cover all modifications, alternative constructions, and equivalents falling within the spirit and scope of the invention as defined in the claims.

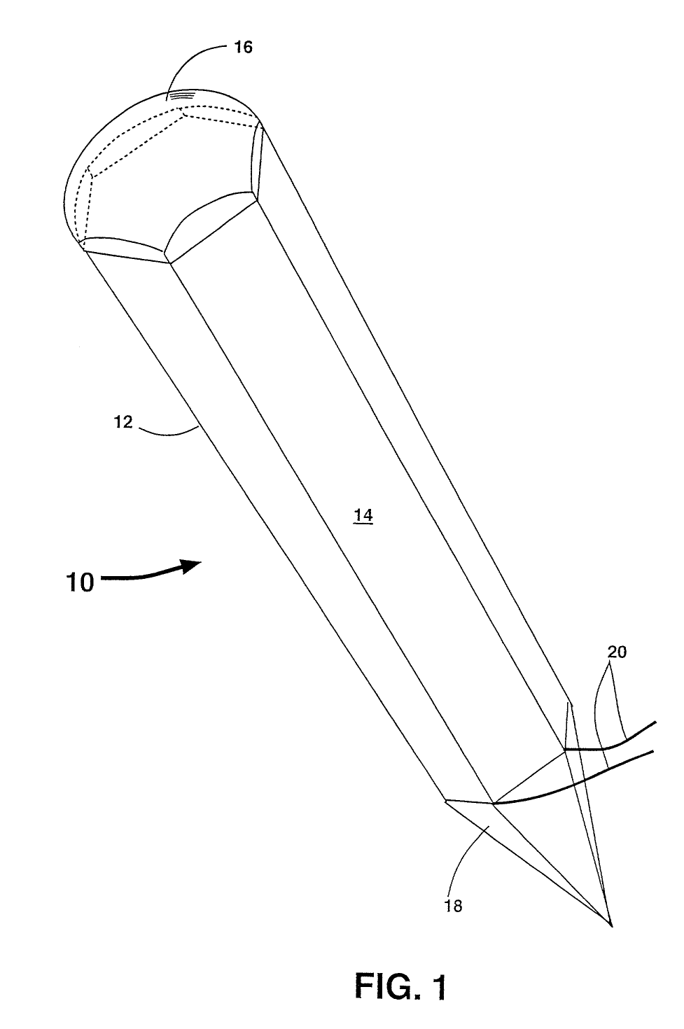

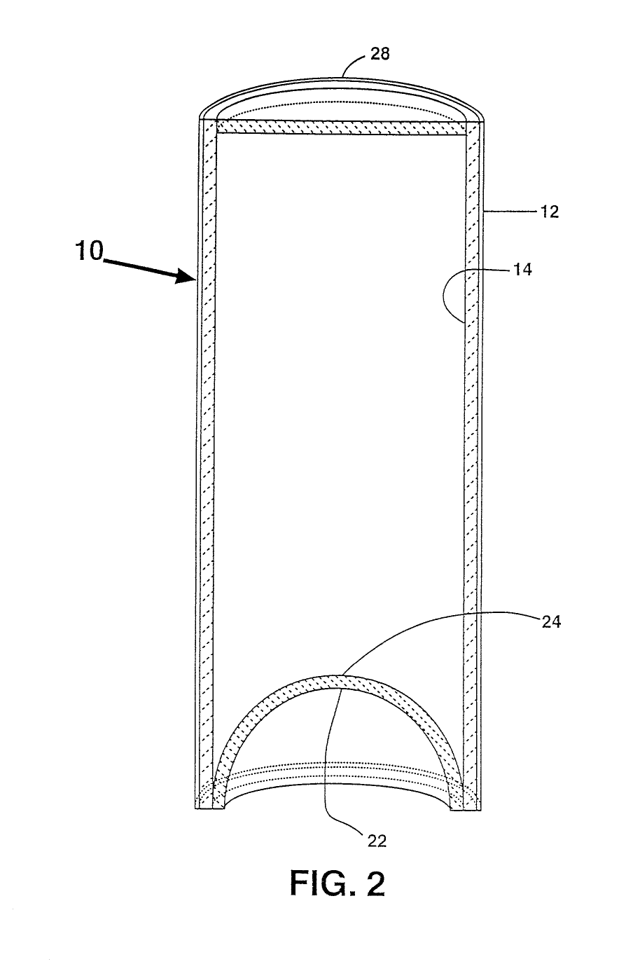

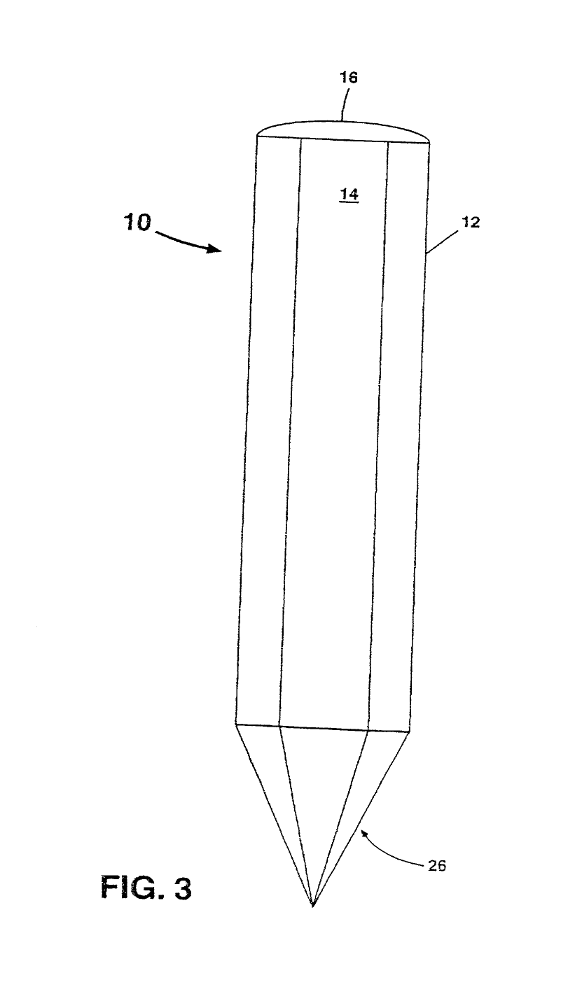

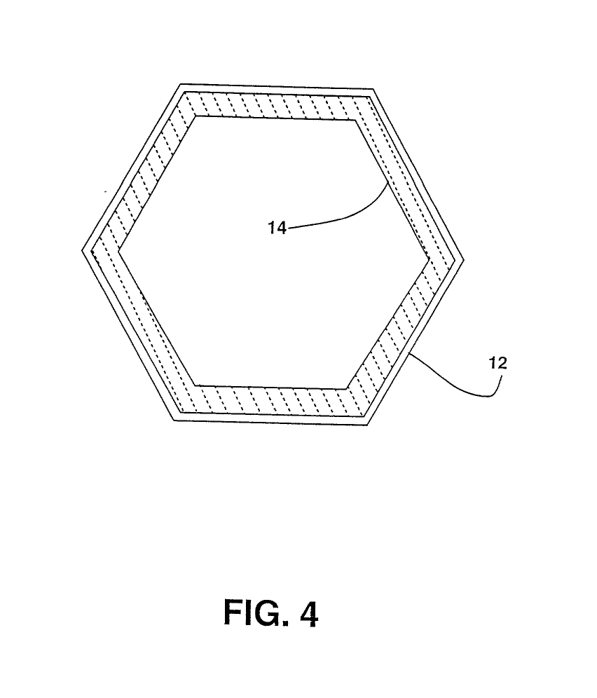

Some of the preferred embodiments of the invention are shown in the FIGS. 1 through 4. The invention is capable of being practiced in a number of preferred embodiments, even though one embodiment may be described in more detail than others. In one preferred embodiment, the solar collector unit can be a tube formed by rolling or folding a rectangular array of solar collectors 14 into a tube and sealing them along the adjoining edge, thus forming a hollow light tube 12, as shown in FIG. 1. This light tube can exists in a number of cross sectional shapes including cylindrical, square tubular, triangular tubular, multi-side tubular such as pentagonal or hexagonal, etc., or any other tubular form. The solar collectors are arranged so that a collecting side is directed toward the interior of the tube thus formed. The device can also include a separate light tube around which solar collectors are formed. This light tube can be a cylinder or another tubular shape of some type of light transparent material, such as acrylic.

Any of the light tubes described above can have the end of the tube which faces the light source sealed with a light transparent panel 28, or by a light focusing lens 16. Any of these tubular structures can also have a reflector 32 in the end of the light tube which is distal from the light source, called the light blocking end. The reflector can be a flat piece of reflecting material, or can be a convex reflector 22, or a faceting reflector 26, in order to reflect light back toward the smooth interior walls of the light tube.

One embodiment of the device which has proved successful is one in which the light tube 12 is made of a solid, light transparent material, such as acrylic. An array of solar collectors 14 is placed around a solid acrylic cylinder, with the collecting side of each solar collector array 14 facing towards the interior of the rod, or towards the long axis of the rod. Electrical connections 20 attach to each solar collector array 14, and allow electricity generated by the solar collector array 14 to be routed away from the solar collector unit 10.

A cylindrical acrylic light tube 12, which is 1½ inches in diameter has proven to be an effective light tube when surrounded by an array of solar collectors. When only a 1½ inch diameter circle of such a solar collector is exposed to sunlight, one would expect to be able to generate approximately the same amount of electricity as a flat disk solar collector 1½ inches in diameter. One might assume that the efficiency of a tube over such a flat disk might be a small percentage more productive than the output of the flat disk, due to better absorption of reflected light. However, it has been found that a solar collector so configured produces as much energy as the solar collector array which surround the tube would produce if they were laid out flat. In other words, with the end of a 1½ inch diameter tubular solar collector exposed to the sun, the electricity generated is equal to a 5 inch by 5 inch flat solar array exposed to the same sun. A solar collector approximately 12 inches long has been utilized and shown to produce as much electricity with 1½ inches exposed to collect light as the solar cells wrapped around the tube, which are approximately 5 inches by 12 inches.

This design allows much more electricity to be generated for a given amount of surface area. Instead of using a large surface area for placement of flat energy gathering cells, using the device of the invention only the light gathering end of the solar collecting unit is exposed to light. Light travels down the length of the solar collecting unit effectively and is bounced from one side to the other until essentially all of the light is absorbed and converted to electrical energy. With this invention, either the surface area for the collection of a certain voltage of light need be much smaller, or for a given surface area, the output of electricity can be much higher than is presently experienced with flat solar cells. With this technology, all but the light gathering end of the solar collectors can be buried in the ground, embedded in the walls and ceilings of buildings, or conveniently hidden inside other structures such as poles, sidewalks, roofs, eves, etc.

It has been found that for the first several feet of 1.5 inch diameter acrylic rod, it is possible to produce 33 to 36 volts of electricity.

In one preferred embodiment, the solid, light transparent tube is made of acrylic, and a suitable length that has been utilized has been 4 inches. In this preferred embodiment, the light gathering lens is a convex dome, approximately equal in size to the light gathering tube. The light reflecting end is a concave end extending into the light gathering tube, and is coated with a reflective finish to enhance reflectance. In tests, a 4 inch long inch long light gathering rod 1½ inches in diameter, wrapped in a sheet of solar collectors, produces 12 volts of electricity, compared with 2 volts which a 1½ inch diameter flat circular solar collector would be expected to produce. This array with longer light gathering rods would produce more volts. A light gathering rod 11.5 inches in length produced 15.3 volts, with a diameter of 1½ inches.

While there is shown and described the present preferred embodiment of the invention, it is to be distinctly understood that this invention is not limited thereto but may be variously embodied to practice within the scope of the following claims. From the foregoing description, it will be apparent that various changes may be made without departing from the spirit and scope of the invention as defined by the following claims.

I claim:

1. A solar collector unit comprising:
a light tube which has a long axis, a light tube wall, a smooth interior surface, an exterior surface, a light collecting end, and a light blocking end, for orientation with said light collecting end toward a light source and said light blocking end away from said light source, and with one or more solar collectors forming said light tube wall, with each solar collector having a collecting side and a non-collecting side, with each of said solar collectors oriented with said collecting side facing said long axis of said light tube;
one or more electrical connections which are connected to said collecting side of said one or more solar collectors, for flow of electricity out of said one or more solar collectors; and whereby
light enters said light tube through said light collecting end, and passes through said smooth interior surface of said light tube, and strikes said one or more solar collectors to produce electricity which flows through said one or more electrical connections.

2. The solar collecting unit of claim 1 in which said light tube is a light transparent material with a smooth inner wall, and in which said solar collector is placed against said exterior or interior wall of said light tube.

3. The solar collecting unit of claim 1 which further includes a convex reflector in said light blocking end of said light tube, for reflecting light back toward said light collecting end of said light tube.

4. The solar collecting unit of claim 1 which further includes a concave reflector in said light blocking end of said light tube, for reflecting light back toward said light collecting end of said light tube.

5. The solar collecting unit of claim 1 which further includes a tube end which is transparent to light and covers said light collecting end of said light tube.

6. The solar collecting unit of claim 1 in which said tube end is a light focusing lens mounted in said light collecting end of said light tube, for focusing and directing light into said light collecting end of said light tube.

7. The solar collecting unit of claim 2 in which said light tube is a cylindrical tube of light transparent material surrounded by solar collectors, with said solar collectors each having a collecting side and a non-collecting side, with each of said solar collectors oriented with said collecting side facing said long axis of said light tube

8. The solar collecting unit of claim 1 in which said light focusing lens is approximately equal in diameter to said light tube.

9. The solar collecting unit of claim 1 in which said light tube is a solid light transparent material.

10. The solar collecting unit of claim 9 in which said light tube is a solid cylindrical rod of light transparent material.

11. A solar collector unit comprising:
a light tube made of a light transparent material, which has a long axis, a light tube wall, a smooth interior surface, an exterior surface, a light collecting end, and a light blocking end, for orientation with said light collecting end toward a light source and said light blocking end away from said light source;
one or more solar collectors adjacent to said light tube wall, with each solar collector having a collecting side and a non-collecting side, with each of said solar collectors oriented with said collecting side facing said long axis of said light tube;
a concave reflector in said light blocking end of said light tube, for reflecting light back toward said light collecting end of said light tube;
a light focusing lens which is mounted in said light collecting end of said light tube, for focusing and directing light into said light collecting end of said light tube;
one or more electrical connections which is connected to said collecting side of said one or more solar collectors, for flow of electricity out of said one or more solar collectors; and whereby
light enters said light tube through said light collecting end, and passes through said smooth interior surface of said light tube, and strikes said one or more solar collectors to produce electricity which flows through said one or more electrical connections.

12. The solar collecting unit of claim 11 in which said light focusing lens is approximately equal in diameter to said light tube.

13. The solar collecting unit of claim 11 in which said light tube is a solid light transparent material.

14. The solar collecting unit of claim 13 in which said light tube is a solid cylindrical rod of light transparent material.

15. A solar collector unit comprising:
a cylindrical light tube which is a solid rod of a light transparent material, which has a long axis, a light tube wall, a smooth interior surface, an exterior surface, a light collecting end, and a light blocking end, for orientation with said light collecting end toward a light source and said light blocking end away from said light source;
one or more solar collectors adjacent to said light tube wall, with each solar collector having a collecting side and a non-collecting side, with each of said solar collectors oriented with said collecting side facing said long axis of said light tube;
a convex reflector in said light blocking end of said light tube, for reflecting light back toward said light collecting end of said light tube;
a light focusing lens which is approximately equal in diameter to said light tube, and which is mounted in said light collecting end of said light tube, for focusing and directing light into said light collecting end of said light tube;
one or more electrical connection which is connected to said collecting side of said one or more solar collectors, for flow of electricity out of said one or more solar collectors; and whereby
light enters said light tube through said light collecting end, and passes through said smooth interior surface of said light tube, and strikes said one or more solar collectors to produce electricity which flows through said one or more electrical connections.

16. The solar collecting unit of claim 15 in which said light focusing lens is approximately equal in diameter to said light tube.

17. The solar collecting unit of claim 15 in which said light tube is a solid cylindrical rod of light transparent material.
